(19) United States
(12) Patent Application Publication
(10) Pub. No.: US 2023/0369256 A1
(43) Pub. Date: Nov. 16, 2023

(54) Multi-Device Power Module Arrangement

(71) Applicant: Infineon Technologies AG, Neubiberg (DE)

(72) Inventors: Kushal Kshirsagar, Warwick, RI (US); Eung San Cho, Torrance, CA (US); Danny Clavette, Greene, RI (US); Wenkang Huang, East Greenwich, RI (US); Angela Kessler, Sinzing (DE)

(21) Appl. No.: 17/742,767

(22) Filed: May 12, 2022

(51) Int. Cl. H01L 23/66; H01L 23/367; H01L 23/13; H05K 1/11; H05K 3/30; H01L 23/495; H01L 23/498

(52) U.S. Cl. CPC H01L 23/66; H01L 23/3675; H01L 23/13; H05K 1/111; H05K 3/301; H01L 23/49503; H01L 23/49541; H01L 23/49872; H05K 2201/10431; H05K 2201/1003

(57) ABSTRACT

A semiconductor assembly includes a carrier including a dielectric substrate and a plurality of contact pads disposed on an upper surface of the carrier, first and second surface mount packages mounted on the carrier, first and second discrete inductors respectively mounted over the first and second surface mount packages, wherein the first and second surface mount packages each comprise lower surface terminals that face and electrically connect with the contact pads from the carrier, wherein the first and second surface mount packages each comprise an upper side that faces away from the carrier, and wherein the first and second discrete inductors are respectively thermally coupled to the upper sides of the first and second surface mount packages.

### BACKGROUND

Power modules are used in many applications such as automotive and industrial applications. A power module may include power devices that are rated to control large voltages and/or currents, e.g., MOSFETs (metal oxide semiconductor field effect transistors), IGBTs (insulated gate bipolar transistors), diodes, etc., and driver devices that are configured to control the power devices. A power module may also include passive electric elements, e.g., inductors, capacitors, etc., that enhance performance, e.g., power efficiency, switching speed, etc. It is desirable to provide a power module with high performance, e.g., high peak efficiency and a high full-load of high heavy-load efficiency, while maintaining a small areal footprint and having robust electrical interconnections.

### SUMMARY

A semiconductor assembly is disclosed. According to an embodiment, the semiconductor assembly comprises a carrier comprising a dielectric substrate and a plurality of contact pads disposed on an upper surface of the carrier, first and second surface mount packages mounted on the carrier, first and second discrete inductors respectively mounted over the first and second surface mount packages, wherein the first and second surface mount packages each comprise lower surface terminals that face and electrically connect with the contact pads from the carrier, wherein the first and second surface mount packages each comprise an upper side that faces away from the carrier, and wherein the first and second discrete inductors are respectively thermally coupled to the upper sides of the first and second surface mount packages.

According to another embodiment, the semiconductor assembly comprises an interposer comprising a plurality of upper surface contact pads disposed on an upper surface of the interposer, first and second surface mount packages mounted on the interposer, the first and second surface mount packages each comprising lower surface terminals that face and electrically connect with the upper surface contact pads from the interposer, and first and second discrete inductors mounted over the first and second surface mount packages, respectively, wherein the first and second surface mount packages are each configured as a half-bridge circuit, wherein the first and second surface mount packages each comprise a switch output terminal that is respectively configured as a switch node of the half-bridge circuit from the first and second surface mount packages, and wherein the switch output terminals of the first and second surface mount packages are respectively electrically connected to first leads from the first and second discrete inductors.

A method of forming a semiconductor assembly is disclosed. According to an embodiment, the method comprises providing a carrier comprising a dielectric substrate and a plurality of contact pads disposed on an upper surface of the carrier, mounting first and second surface mount packages on the carrier, and mounting first and second discrete inductors respectively over the first and second surface mount packages, wherein the first and second surface mount packages each comprise lower surface terminals that face and electrically connect with the contact pads from the carrier, wherein the first and second surface mount packages each comprise an upper side that faces away from the carrier, and wherein first and second discrete inductors are respectively thermally coupled to the upper sides of the first and second surface mount packages.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a semiconductor assembly with a carrier, surface mount packages mounted on the carrier, and discrete inductors mounted over the surface mount packages, according to an embodiment.

FIG. 2, which includes FIGS. 2A and 2B, illustrates a plan-view of the semiconductor assembly from FIG. 1, according to an embodiment. FIG. 2A illustrates a plan-view of the semiconductor assembly before the mounting of the discrete inductors and FIG. 2B illustrates a plan-view of the semiconductor assembly after the mounting of the discrete inductors.

FIG. 3 illustrates a supply voltage configuration of a carrier that is configured as an interposer mounted on a circuit board, according to an embodiment.

FIG. 4 illustrates a supply voltage configuration of a carrier of a carrier that is configured as an interposer mounted on a circuit board, according to another embodiment.

FIG. 5 illustrates a semiconductor assembly with a carrier, surface mount packages mounted on the carrier, and discrete inductors mounted over the surface mount packages, according to another embodiment.

FIG. 6 illustrates a semiconductor assembly with a carrier, surface mount packages mounted on the carrier, and discrete inductors mounted over the surface mount packages, according to another embodiment.

FIG. 7 illustrates a semiconductor assembly with a carrier, surface mount packages mounted on the carrier, and discrete inductors mounted over the surface mount packages, according to another embodiment.

FIG. 8 illustrates a semiconductor assembly with a carrier, surface mount packages mounted on the carrier, and discrete inductors mounted over the surface mount packages, according to another embodiment.

### DETAILED DESCRIPTION

Described herein are embodiments of a semiconductor assembly comprising surface mount packages mounted on a carrier and discrete inductors mounted over the surface mount packages. Each grouping of a surface mount package with a discrete inductor may form a power stage of a power conversion circuit, with the surface mount package comprising a half-bridge circuit, and the discrete inductor being arranged as an output inductance with the half-bridge circuit. Electrical connection between the discrete inductors and the surface mount packages may be provided via the carrier, or via connections between the upper sides of the surface mount packages and exposed lead portions of the discrete inductors, or both. In addition to being electrically connected to the circuit of the surface mount packages, the discrete inductors may also be configured as a heat sink device that extracts heat away from the surface mount packages during operation. To this end, the discrete inductors may comprise a metal element arranged within an insulating outer body that is exposed at both the bottom side and an upper side of the outer body. This metal element can be thermally coupled to the surface mount package by a thermally conducive material. Optionally, the connection between the metal element and the surface mount package can be an electrical connection that is redundant to or replaces a lower-side connection of the surface mount package.

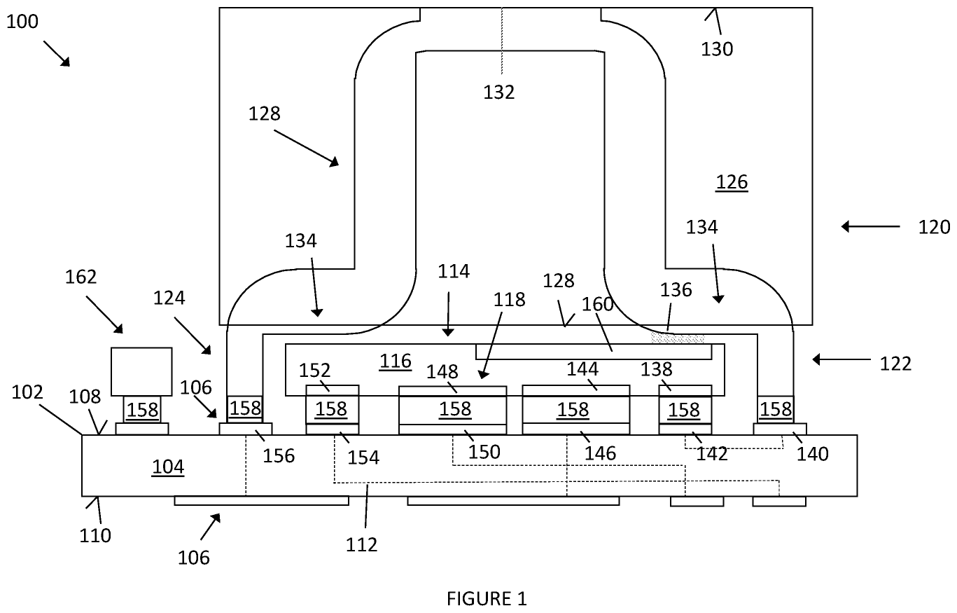

Referring to FIG. 1A, a semiconductor assembly 100 comprises a carrier 102. The carrier 102 comprises a dielectric substrate 104 and a plurality of contact pads 106 disposed on an upper surface 108 of the carrier 102. The dielectric substrate 104 can comprise electrically insulating materials such as ceramics, epoxy materials, plastics, glass materials, oxides, nitrides, pre-preg materials, etc. The contact pads 106 can be formed from conductive metals such as a copper, aluminum, zinc, tungsten, nickel, etc.

According to an embodiment, the carrier 102 is an interposer that is configured to be mounted on a further carrier (not shown in FIG. 1A). This further carrier can be an electronics carrier that accommodates the mounting of multiple electronics components thereon, e.g., a PCB (printed circuit board), DBC (direct bonded copper) substrate, AMB (active metal brazed) substrate, IMS (insulated metal substrate), etc. The carrier 102 that is configured as an interposer may provide electrical interconnection between the components mounted on the interposer and the further carrier that the interposer is mounted on. Moreover, the carrier 102 that is configured as an interposer may provide electrical interconnection between the various components mounted on the interposer. FIG. 1 illustrates an example of a carrier 102 that is configured as an interposer and comprises a further plurality of contact pads 106 disposed on a lower surface 110 of the carrier 102 that is opposite from the upper surface 108. The carrier 102 that is configured as an interposer comprises a network of internal electrical connections 112 that are formed within the dielectric substrate 104 between groups of contact pads 106 that are disposed on the upper surface 108 and/or between contact pads 106 that are disposed on the upper surface 108 and contact pads 106 that are disposed on the lower surface 110. Instead of being configured as an interposer, the carrier 102 may be a global circuit carrier akin to the further carrier described above that accommodates the mounting of multiple electronics components thereon, e.g., a PCB (printed circuit board), DBC (direct bonded copper) substrate, AMB (active metal brazed) substrate, IMS (insulated metal substrate), etc. In that case, the contact pads 106 that are disposed on the lower surface 110 may be omitted.

According to an embodiment, the carrier 102 is a laminate device. In this case, the dielectric substrate 104 may comprise one or more core laminate layers comprising, e.g., pre-preg material such as FR-4, FR-5, CEM-4 and/or resin materials such as bismaleimide trazine (BT) resin. The contact pads 106 may correspond to structured layers of metallization that are bonded to the constituent laminate layers. The internal electrical connections 112 may be provided by structured layers of metallization that are between two of the constituent laminate layers and through-via structures formed in the constituent laminate layers.

The semiconductor assembly 100 additionally comprises a surface mount package 114 mounted on the carrier 102. The surface mount package 114 comprises a package body 116 with one or more semiconductor dies (not seen) embedded within the package body 116. According to an embodiment, the surface mount package 114 comprises a power semiconductor die that is rated to accommodate voltages of at least 100V and may be on the order of 500V or more and/or currents of at least 1 A and may be on the order of 10 A or more. Examples of these power semiconductor dies include MOSFETs (Metal Oxide Semiconductor Field Effect Transistors), IGBTs (Insulated Gate Bipolar Transistors), and HEMTs (High Electron Mobility Transistors), for example. The surface mount package 114 comprises lower surface terminals 118 disposed at a lower side of the package body 116. The lower surface terminals 118 face and electrically connect with the contact pads 106 from the carrier 102, the details of which will be described below. The lower surface terminals 118 can be formed from conductive metals such as a copper, aluminum, zinc, tungsten, nickel, etc.

According to an embodiment, the surface mount package 114 is an embedded package. In that case, the package body 116 may be formed from multiple constituent layers of dielectric material that are laminated (stacked) on top of one another. The semiconductor die or dies of the package may be embedded within openings in these constituent laminate layers, and may be sealed by a resin. Each constituent laminate layer can comprise a rigid dielectric material that is suitable for semiconductor device encapsulation. Examples of these dielectric materials include epoxy materials, blended epoxy and glass fiber materials such as FR-4, FR-5, CEM-4, etc., and resin materials such as bismaleimide trazine (BT) resin. An embedded package may also include multiple layers of metallization, e.g., copper, aluminum, etc., and alloys thereof, formed on top of at least some of the constituent laminate layers. These layers of metallization can be structured to form internal electrical interconnects within the package body 116 as well as the terminals that are exposed at the outer surfaces of the package body 116. Conductive vias, e.g., vias comprising tungsten, copper, etc., may be provided in openings that extend through the constituent layers of dielectric material to provide vertical electrical interconnect. Due to the electrical interconnect provided by the embedded package type, an embedded package does not require a lead frame. Therefore, the surface mount package 114 may be devoid of a die pad that accommodates the semiconductor dies and/or devoid of conductive leads that are formed from the same lead frame structure as a die pad.

According to another embodiment, the surface mount package 114 is a molded package. In that case, the package body 116 is formed from an electrically insulating mold compound comprising, e.g., epoxy, thermosetting plastic, etc. This type of package may comprise a metal lead frame with a die pad that accommodates the mounting of one or more semiconductor dies thereon. The metal lead frame may form the lower surface terminals 118 as well. The semiconductor die or dies may be mounted on the metal lead frame, electrical interconnections such as bond wires, clips etc. may be formed, and the package body 116 may then be formed by a molding process, such as injection molding, transfer molding, compression molding, etc.

According to an embodiment, the surface mount package 114 is configured as a power module. In this configuration, the surface mount package 114 may comprise a power conversion circuit such as a single or multi-phase half-wave rectifier, single or multi-phase full-wave rectifier, voltage regulator, inverter, etc. The power conversion circuit may comprise semiconductor dies configured as power switching devices (e.g., MOSFETs, IGBTs, HEMTs) and a semiconductor die configured as a driver die that controls a switching operation of the power switching devices. The power module may comprise two power transistor dies that form the high-side switch and low-side switch of a half-bridge circuit and a third semiconductor die that is configured as a driver device (e.g., a CMOS logic device) that is configured to control a switching operation of the high-side switch and low-side switch. In another embodiment, the surface mount package 114 may comprise two power transistor dies that form the low-side switch of two separate half-bridge circuits, with another package comprising two power transistor dies that form the high-side switch of the same two separate half-bridge circuits, or vice-versa.

The semiconductor assembly 100 further comprises a discrete inductor 120 that is mounted over the surface mount package 114. The discrete inductor 120 comprises first and second leads 122, 124 that are exposed from an outer body 126 and a metal element 128 arranged within the outer body 126. In the mounted position, a lower side 130 of the outer body 126 faces the carrier 102 and an upper side 130 of the outer body 126 faces away from the carrier 102. The outer body 126 comprises an electrically insulating material such as epoxy, resin, ceramic, etc. The metal element 128 and the first and second leads 122, 124 can be formed from a conductive metal, e.g., copper, aluminum, nickel, alloys thereof, etc. The metal element 128 and the first and second leads 122, 124 can be parts of a continuous structure or can comprise multiple metal elements that are attached to one another. The metal element 128 forms the inductive winding of the discrete inductor 120 that provides a defined inductance between the first and second leads 122, 124. The metal element 128 forms internal lead parts 134 of the of the discrete inductor 120 that connect the inductive winding to the first and second leads 122, 124. The parts 134 of the metal element 128 that connect with the first and second leads 122, 124 may be exposed at a lower side 128 of the outer body 126. Additionally, the metal element 128 is configured to comprises a heat radiating block 132 that is exposed at the upper side 130 of the outer body 126 of the discrete inductor 120. As the material of the metal element has a significantly higher thermal conductivity than that of the outer body 126, e.g., on the order of 5 to 50 times greater, the provision and arrangement of the metal element 128 in the outer body 126 forms a highly thermally conductive path for heat transfer between the lower side 128 of the outer body 126 and the upper side 130 of the outer body 126.

The discrete inductor 120 is mounted on the carrier 102 such that the metal element 128 is thermally coupled to the upper side of the surface mount package 114. In this context, thermally coupled means that the metal element 128 is either in direct contact with the upper side of the surface mount package 114 or a thermally conductive material 136 (e.g., as shown) contacts the metal element 128 and the upper side of the surface mount package 114. This thermally conductive material 136 can be an electrically isolating material, such as a silicone-based gap filer material or a thermal interface material (TIM). Alternatively, this thermally conductive material 136 can be an electrically conductive material, such as a solder, sinter or conductive glue. A thermal conductivity of the thermally conductive material 136 can be at least 0.01 W/cm-K (watts per ceintimeter-Kelvin), and more preferably at least 0.1 W/cm-K or higher.

The semiconductor assembly 100 may have the following electrical connectivity. The surface mount package 114 may comprise a first one 138 of the lower surface terminals 118 that corresponds to a switch output terminal pad. This switch output terminal pad may connect with a switch output (SW) of a half-bridge circuit from the surface mount package 114. The first one 138 of the lower surface terminals 118 may be electrically connected to the first lead 122 of the discrete inductor 120 via the carrier 102. This electrical connection may be provided by first and second ones 140, 142 of the contact pads 106 that are disposed on the upper surface 108 of the carrier 102 and are immediately adjacent to one another. These first and second ones 140, 142 of the contact pads 106 may be electrically connected to one another by the internal electrical connections 112 of the carrier 100. The surface mount package 114 may comprise a second one 144 of the lower surface terminals 118 that corresponds to a ground terminal pad of the surface mount package 114. This ground terminal pad of the surface mount package 114 may provide a reference potential to the half-bridge circuit. The second one 144 of the lower surface terminals 118 may be electrically connected to a ground (GND) potential via the carrier 102. As shown, the second one 144 of the lower surface terminals 118 faces and electrically connects with a third one 146 of the contact pads 106 disposed on the upper surface 108 of the carrier 102, which may be configured to provide the ground potential. In the case of an interposer, the third one 146 of the contact pads 106 may be connected to one of the contact pads 106 disposed on the lower surface 110 of the carrier 102 by the internal electrical connections 112 of the carrier 100. The surface mount package 114 may comprise a third one 148 of the lower surface terminals 118 that corresponds to a voltage input pad of the surface mount package 114. The voltage input pad may be arranged to provide a voltage supply to the half-bridge circuit. The third one 148 of the lower surface terminals 118 of the surface mount package 114 may be electrically connected to a voltage input (VIN) via the carrier 102. As shown, the third one 148 of the lower surface terminals 118 faces and electrically connects with a fourth one 150 of the contact pads 106 disposed on the upper surface 108 of the carrier 102, which may be configured to provide the voltage input (VIN). In the case of an interposer, the fourth one 150 of the contact pads 106 may be connected to one of the contact pads 106 disposed on the lower surface 110 of the carrier 102 by the internal electrical connections 112 of the carrier 100. The surface mount package 114 may comprise a fourth one 152 of the lower surface terminals 118 that corresponds to an I/O pad of the surface mount package 114. The I/O pad may be arranged to control a switching operation of the half-bridge circuit. The fourth one 152 of the lower surface terminals 118 of the surface mount package 114 may be electrically connected to an I/O signal via the carrier 102. As shown, the fourth one 152 of the lower surface terminals 118 faces and electrically connects with a fifth one 154 of the contact pads 106 disposed on the upper surface 108 of the carrier 102, which may be configured to provide the I/O signal. In the case of an interposer, the fifth one 154 of the contact pads 106 may be connected to one of the contact pads 106 disposed on the lower surface 110 of the carrier 102 by the internal electrical connections 112 of the carrier 100. The second lead 124 of the discrete inductor 120 may form an output terminal of the power conversion circuit comprising the surface mount package 114. This output terminal may be accessed via the carrier 102. As shown, the second lead 124 of the discrete inductor 120 faces and electrically connects with a sixth one 156 of the contact pads 106 disposed on the upper surface 108 of the carrier 102. In the case of an interposer, the sixth one 156 of the of the contact pads 106 may be connected to one of the contact pads 106 disposed on the lower surface 110 of the carrier 102 by the internal electrical connections 112 of the carrier 100.

Each of the above-described connections between the lower surface terminals 118 and the contact pads 106 and/or between the first and second leads 122, 124 and the contact pads 106 can be effectuated by a connection material 158 that forms an electrical and mechanical connection, e.g., solder, sinter, conductive glue, etc. In the case that the carrier 102 is not an interposer and instead is a global circuit carrier, the connections between the contact pads 106 disposed on the upper surface 108 and the contact pads 106 disposed on the lower surface 110 of the carrier 102 may be omitted and these signals may be routed by the carrier 102 itself, e.g., by conductive tracks and/or interconnect elements such as bond wires and clips.

According to an embodiment, the upper side of the surface mount package 114 that faces the discrete inductor 120 comprises one or more exposed metal pads 160. In the case of an embedded package that is constructed from a laminate package body 116, the exposed metal pads 160 may be provided from a structured portion of a metallization layer that is part of the package construction. In the case of a molded package that is encapsulated within an electrically insulating mold compound, the exposed metal pads 160 may be provided from an interconnect clip or heat slug. At least one of the exposed metal pads 160 may be configured as an active device terminal of the surface mount package 114. That is, a metal pad 160 may be configured as an externally accessible point of electrical contact to the circuits of the surface mount package 114 in a similar manner as the lower surface terminals 118 of the surface mount package 114. Separately or in combination, at least one of the exposed metal pads 160 may be configured as a dummy pad, i.e., a metal structure that is disconnected from the circuit elements contained within the surface mount package 114. In that case, the dummy pad can be used for cooling purposes.

According to an embodiment, at least one of the exposed metal pads 160 is thermally coupled to the discrete inductor 120. In this way, thermal heat transfer is enhanced by connecting the discrete inductor to a metal surface. As shown, the discrete inductor 120 is arranged such that the part 134 of the metal element 128 that connects with the first lead 122 and is exposed at the lower side 128 of the outer body 126 is thermally coupled to one of the metal pads 160 by the thermally conductive material 136. This thermal connection may also form an electrical connection. For example, the metal pad 160 that is thermally coupled to the part 134 of the metal element 128 that connects with the first lead 122 may be a first output pad of the surface mount package 114 that is electrically equivalent to one of the lower surface terminals 118. In a particular embodiment, this first output pad may form the same node as the first one 138 of the lower surface terminals 118, which as described above may correspond to a switch output (SW) of a half-bridge circuit from the surface mount package 114. In this case, the thermally conductive material 136 may be an electrically conductive attachment material, such as solder or sinter. In this way, the electrical resistance of the output connection between the surface mount package 114 and the first lead 122 of the discrete inductor 120 may be enhanced.

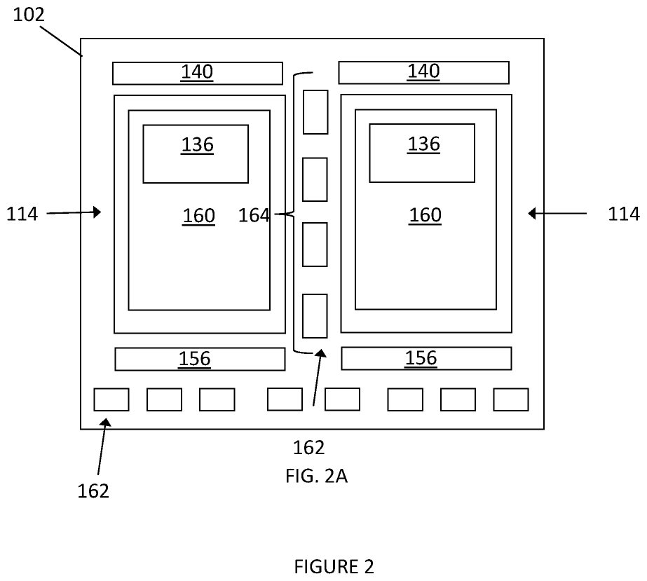

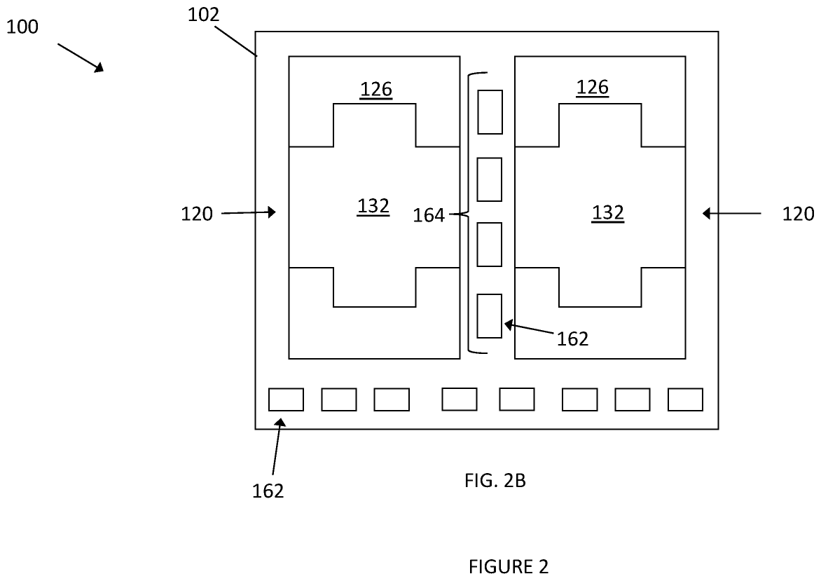

Referring to FIG. 2, the semiconductor assembly 100 may comprise multiple pairings of the the surface mount package 114 and the discrete inductor 120 configuration shown in the cross-sectional view of FIG. 1. Each sub-assembly comprising one of the surface mount packages 114 and one of the discrete inductors 120 can correspond to a phase of a power conversion circuit. These sub-assemblies can be arranged to build any number of phases of a power conversion circuit, e.g., three, four, six, eight, etc, wherein each can be represented by the cross-sectional view of FIG. 1A and the corresponding discussion.

FIG. 2A may represent an intermediate processing stage after the mounting of the surface mount packages 114 and before the mounting of the discrete inductors 120. As shown, the semiconductor assembly 100 may comprise first and second ones of the first and second surface mount packages 114 mounted on the carrier 100. After the mounting of the first and second surface mount packages 114, the thermally conductive material 136 may be applied to the upper side of the first and second surface mount packages 114. For example, a screen-printing process may be performed to form the thermally conductive material 136 as regions of solder material on the metal pads 160 of the first and second surface mount packages 114.

The semiconductor assembly 100 may further comprise additional discrete passive elements 162 mounted on the carrier 102. The additional discrete passive elements 162 can comprise any type of discrete device, e.g., resistor, capacitor, inductor. According to an embodiment, at least some of the additional discrete passive elements 162 may be discrete capacitors that are part of the power conversion circuits formed by the surface mount packages 114, e.g., resonant capacitors, output capacitors, etc. The additional discrete passive elements 162 can be mounted on the contact pads 106 of the carrier 102 and electrically connected to the lower surface terminals 118 of the first and second surface mount packages 114 via the carrier 102 in a similar manner as described above. In the depicted embodiment, the semiconductor assembly 100 comprises a first group 164 of the additional discrete passive elements 162 arranged laterally between the sub-assemblies of the first and second surface mount packages 114. This arrangement provides increased space-efficiency.

Referring to FIG. 2B, first and second ones of the discrete inductors 120 are respectively mounted over the first and second surface mount packages 114. The discrete inductors 120 can be mounted so that the thermally conductive material 136 contacts the lower side of the discrete inductors including the part 134 of the metal element 128 that connects with the first lead 122. A reflow process may be performed to form solder connections to the first and second leads 122, 124. The thickness of the thermally conductive material 136 may be selected to ensure appropriate contact across a range of dimensional tolerances for the elements, e.g., a length variation in the first and second leads 122, 124.

As can be seen in FIG. 2B, the heat radiating block 132 of the discrete inductor 120 may be configured to provide a large metal surface area that is exposed from the outer body, thus allowing for efficient radiation of heat. For example, the heat radiating block 132 may represent a significant proportion of the upper surface area of the discrete inductor 120, e.g., 50% are more. Separately or in combination, the heat radiating block 132 may extend to outer sidewalls of the outer body 126 and may extend along the outer sidewalls of the outer body 126, thus providing additional exposed metal surface area. As a result, thermal dissipation capability is enhanced.

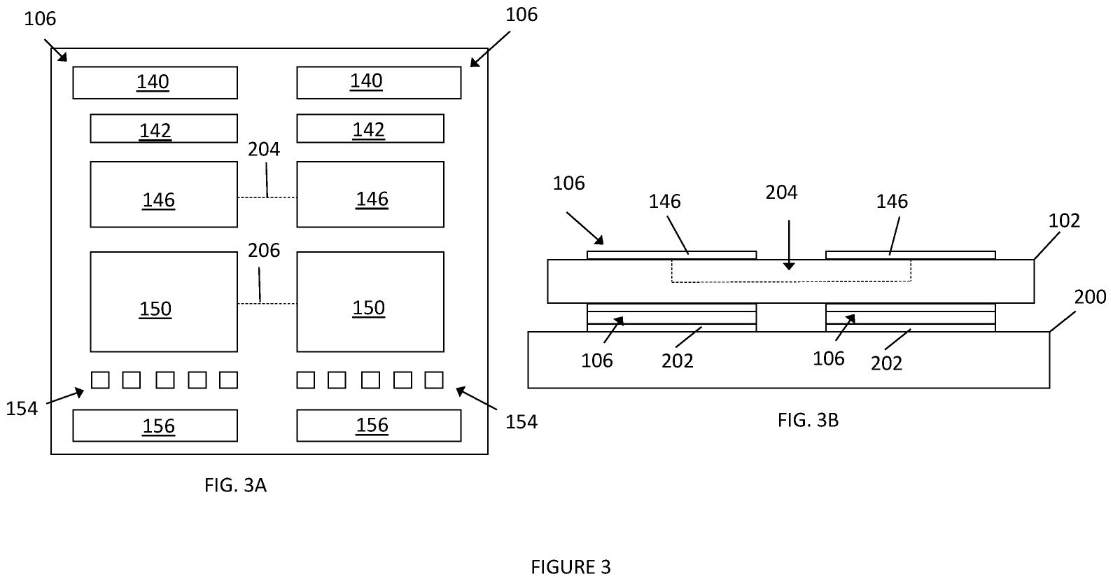

Referring to FIG. 3, an electrical connection arrangement of the semiconductor assembly 100 is schematically depicted, according to an embodiment. In this embodiment, the carrier 106 is configured as an interposer and the assembly 100 further comprises a circuit board 200 comprising upper surface contact pads 202. The circuit board 200 may be a PCB that accommodates the mounting of multiple carriers 106 that are configured as an interposer and/or additional electronic elements. The carrier 106 is mounted on the the circuit board 200 with the contact pads 106 that are disposed on the lower surface 110 facing and electrically connect with upper surface contact pads 202 of the circuit board 200. An electrically conductive joining material such as solder or sinter may be used to effectuate this connection.

In the embodiment of FIG. 3, the carrier 106 that is configured as an interposer is configured to provide common ground and input connections to the first and second surface mount packages 114 when mounted thereon. As shown in FIG. 3A, the carrier 102 comprises a first electrical connection 204 between two of the third ones 146 of the contact pads 106 disposed on the upper surface 108 of the carrier 102. As explained above, the third ones 146 of the contact pads 106 may be configured to provide the ground potential to the second ones 144 of the lower surface terminals 118 from the surface mount packages 114. As shown in FIG. 3B, the first electrical connection 204 may form a common ground connection that is within the carrier 102 and connects the ground terminal pads of the first and second surface mount packages 118 together. That is, the two third ones 146 of the contact pads 106 that are respectively connected to the first and second surface mount packages 114 may be connected to one another by a conductive connection that is within the carrier 102. This conductive connection may be provided by a surface metallization of the carrier 102 and/or by the electrical interconnection tracks 112 that are formed within the carrier 102. As also shown in FIG. 3A, the carrier comprises a second electrical connection 206 between two of the fourth ones 150 of the contact pads 106 disposed on the upper surface 108 of the carrier 102. As explained above, the fourth ones 150 of the contact pads 106 may be configured to provide the voltage input (VIN) to the third ones 148 of the lower surface terminals 118 from the surface mount packages 114. The second electrical connection 206 may form a common voltage supply connection within the carrier 102 that connects the voltage input pads of the first and second surface mount packages 114 together in a similar manner as the first electrical connection 204 shown in FIG. 3B.

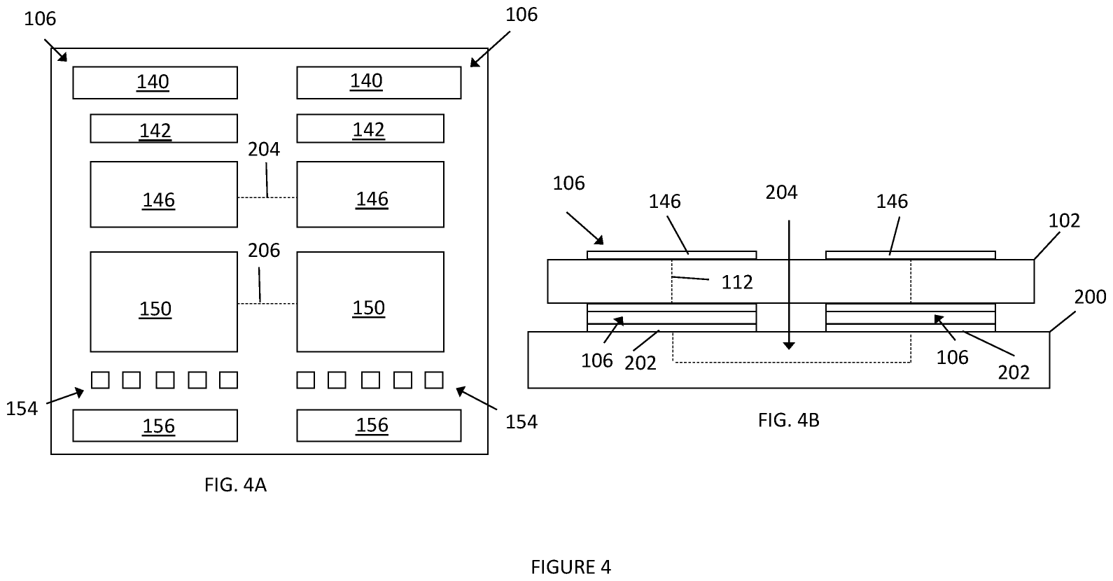

Referring to FIG. 4, an electrical connection arrangement of the semiconductor assembly 100 is schematically depicted, according to another embodiment. In this embodiment, the first and second electrical connections 204, 206 are provided within the circuit board 200 instead of the carrier 106 that is configured as an interposer. Thus, the first electrical connection 204 may form a common ground connection that is within the circuit board 200 and connects the ground terminal pads of the first and second surface mount packages 118 together. Likewise, the second electrical connection 206 may form a common voltage supply connection that is within the circuit board 200 and connects the voltage input pads of the first and second surface mount packages 114 together. As shown in FIG. 4B, the carrier 106 that is configured as an interposer may be configured to provide vertical connections for third ones 146 of the contact pads 106 associated with the ground connection. The circuit board 200 can comprise internal interconnect tracks and/or metallization structures on a surface of the circuit board 200 to complete the first electrical connection 204. The carrier 102 and the circuit board 200 may be configured in a similar manner to provide the second electrical connection 206 between the fourth ones 150 of the contact pads 106.

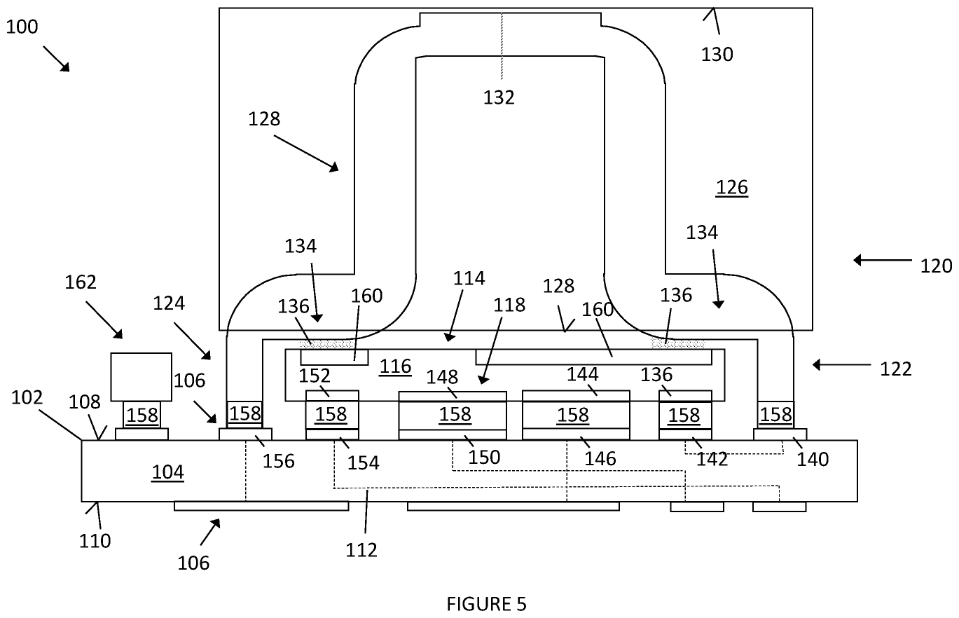

Referring to FIG. 5, the semiconductor assembly 100 is shown, according to another embodiment. In this embodiment, the surface mount package 114 comprises an additional exposed metal pad 160 that is thermally coupled to the part 134 of the second lead 124 that is exposed from the lower side 130 of the outer body 126. According to an embodiment, the additional exposed metal pad 160 that is coupled to the second lead 124 is configured as a dummy pad. Thus, the coupling of the second lead 124 to the metal pad 160 does not alter the electrical connectivity of the circuit. Instead, this thermal coupling arrangement forms a separate thermal dissipation paths between the upper side of the surface mount package 114 and the heat radiating block 132. That is, both parts of the metal element 128 that are connected with the first and second leads 122, 124 form thermal dissipation paths to the heat radiating block 132.

According to an embodiment, the thermally conductive material 136 used to couple the part 134 of the first lead 122 to the metal pad 160 which forms a device terminal is the same material used to couple the part 134 of the second lead 124 to the metal pad 160 which forms the dummy pad. For example, the thermally conductive material 136 can be a solder material. This allows for a common solder application process whereby the solder material is formed on both of the metal pads 160 and the discrete inductor is subsequently mounted over the surface mount package 114 and the solder is reflowed. As a result, the first lead 122 is soldered to the metal pad 160 which forms a first output pad and the second lead 124 is soldered to the metal pad 160 which forms a dummy pad. Because the second lead 124 is soldered to an electrically inactive dummy pad, the use of solder does not disrupt the electrical connectivity of the circuit.

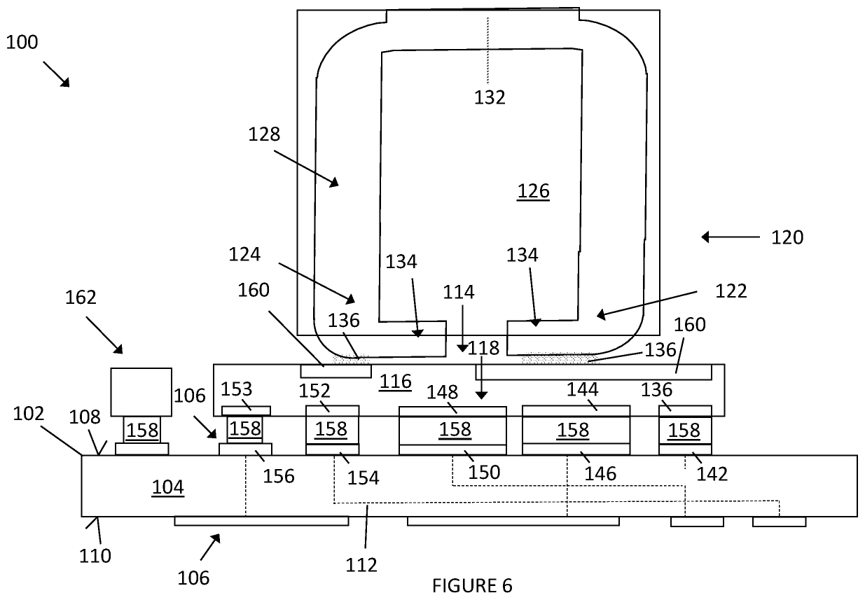

Referring to FIG. 6, the semiconductor assembly 100 is shown, according to another embodiment. In this embodiment, the surface mount package 114 comprises an additional exposed metal pad 160. Each one of the first and second leads 122, 124 are thermally coupled to one of the exposed metal pads by the thermally conductive material 136. Different to the previous embodiment, in this embodiment, the exposed metal pad 160 that is coupled to the second lead 124 may be an active device terminal that is electrically connected to the discrete inductor. In particular, the exposed metal pad 160 that is coupled to the second lead 124 can be configured as a second output pad of the surface mount package 114. This second output pad can be configured to provide the equivalent electrical connection to the connection between the second lead 124 and the sixth one 156 of the contact pads 106 in the embodiment described with reference to FIG. 1. To this end, the surface mount package 114 may comprise a through-via structure that electrically connects the exposed metal pad 160 that is coupled to the second lead 124 with a fifth one 153 of the lower surface terminals 118 that faces and electrically connects with the sixth one 156 of the contact pads 106.

As shown in FIG. 6, the first and second leads 122, 124 of the discrete inductor 120 may bend inward such that ends of the first and second leads 122, 124 are disposed over the upper side of the surface mount package 114. That is, the discrete inductor 120 is configured to form a direct electrical connection at the upper side of the surface mount package 114 without connecting to the carrier 102. In this way, an advantageous space-efficiency can be realized while also providing the advantageous heat dissipation to the surface mount package 114 via the interposer 120. In this arrangement, the electrical connections between the first and second leads 122, 124 and the the contact pads 106 may be thermally conductive material 136 that is also electrically conductive, e.g., solder, sinter, etc.

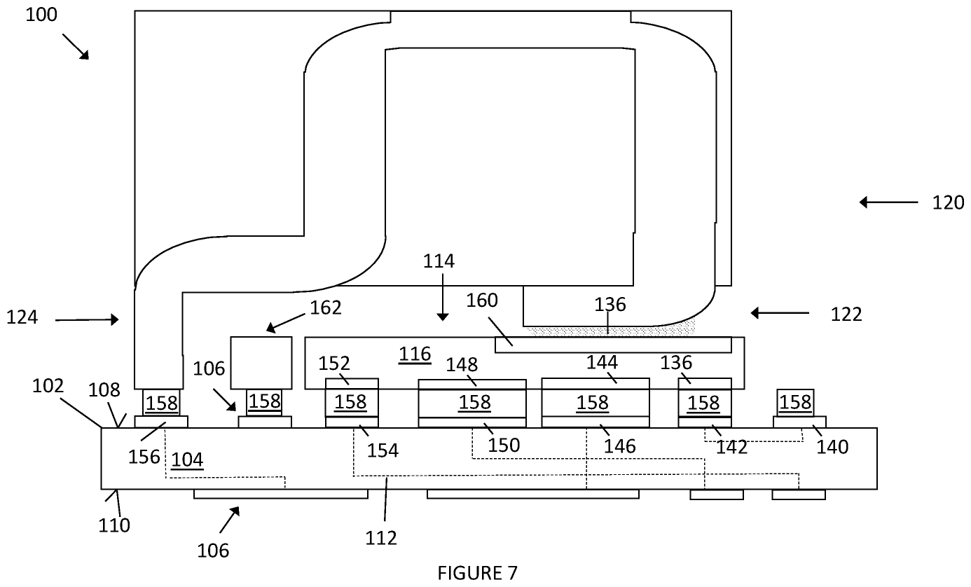

Referring to FIG. 7, the semiconductor assembly 100 is shown, according to another embodiment. In this embodiment, the first lead 122 is bent inward such that the end of the first lead 122 is disposed over the upper side of the surface mount package 114. The first lead 122 may be thermally and electrically connected to the metal pad 160 in a similar manner as described above. Meanwhile, the second lead 124 bends outward and connects with the sixth one 156 of the of the contact pads 106 and may form an output connection in a similar manner as previously described. As shown, at least some of the additional discrete passive elements 162 can be mounted in a lateral region between the the second lead 124 and the surface mount package 114.

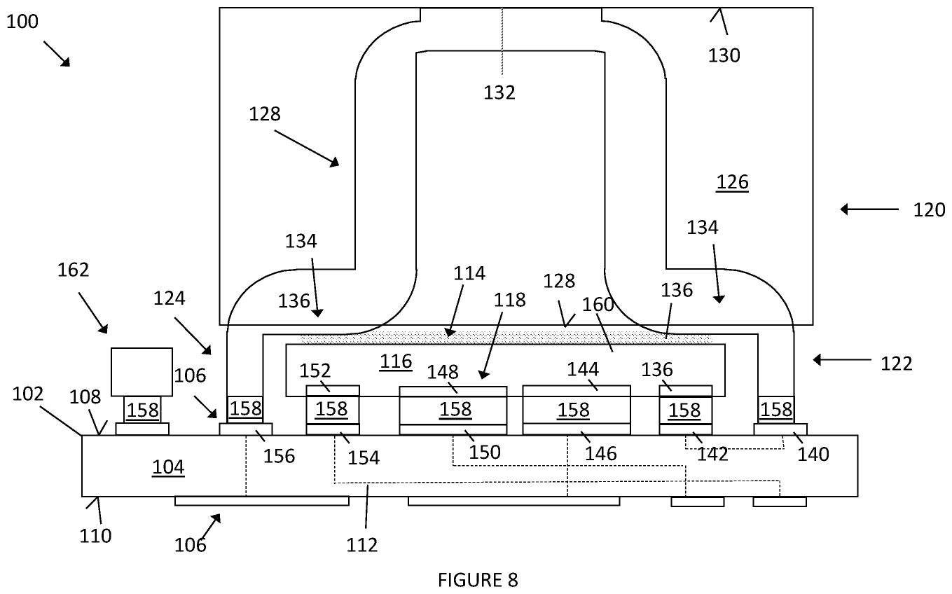

Referring to FIG. 8, the semiconductor assembly 100 is shown, according to another embodiment. In this embodiment, the parts 134 of the first and second leads 122, 124 that are exposed from the lower side 130 of the outer body 126 are both thermally coupled to the surface mount package 114 by a single region of the thermally conductive material 136. In this case, the thermally conductive material 136 does not form an electrical connection. Instead, the thermally conductive material 136 serves purely a cooling function by thermally coupling the surface mount package 114 to the metal element 128 of the inductor 120. For example, the thermally conductive material 136 can be an electrically isolating material such as a thermal interface material (TIM) or gap-filler material. Separately or in combination, the upper side of the surface mount package 114 can be devoid of the metal pads 160 which form electrical terminals (as shown) or the metal pads 160 can be dummy terminals as previously described.

Although the present disclosure is not so limited, the following numbered examples demonstrate one or more aspects of the disclosure.

Example 1. A semiconductor assembly, comprising a carrier comprising a dielectric substrate and a plurality of contact pads disposed on an upper surface of the carrier; first and second surface mount packages mounted on the carrier; first and second discrete inductors respectively mounted over the first and second surface mount packages, wherein the first and second surface mount packages each comprise lower surface terminals that face and electrically connect with the contact pads from the carrier,

wherein the first and second surface mount packages each comprise an upper side that faces away from the carrier, and wherein the first and second discrete inductors are respectively thermally coupled to the upper sides of the first and second surface mount packages.

Example 2. The semiconductor assembly of example 1, wherein the first and second discrete inductors each comprise an outer body of electrically insulating material, a metal element arranged within the outer body, and first and second leads that are exposed from the outer body, wherein the outer body of each of the first and second discrete inductors comprises a lower side that faces the carrier and an upper side that faces away from the carrier, and wherein the metal element of each of the first and second discrete inductors comprises a heat radiating block that is exposed at the upper side of the outer body of the respective first and second discrete inductors.

Example 3. The semiconductor assembly of example 2, wherein the upper sides of the first and second surface mount packages each comprise one or more exposed metal pads, and wherein the one or more exposed metal pads of the first and second surface mount packages are respectively thermally coupled to the metal element of the first and second discrete inductors.

Example 4. The semiconductor assembly of example 3, wherein the one or more exposed metal pads of the first and second surface mount packages comprise a first output pad, and wherein the first leads of the first and second discrete inductors are respectively electrically connected to the first output pads of the first and second surface mount packages.

Example 5. The semiconductor assembly of example 4, wherein the second leads of the first and second discrete inductors are respectively electrically connected to one of the contact pads disposed on the upper surface of the carrier.

Example 6. The semiconductor assembly of example 4, wherein the one or more exposed metal pads of the first and second surface mount packages comprise a dummy pad, wherein the first leads of the first and second discrete inductors are respectively soldered to the first output pads of the first and second surface mount packages, and wherein the second leads of the first and second discrete inductors are respectively soldered to the dummy pads of the first and second surface mount packages.

Example 7. The semiconductor assembly of example 4, wherein the one or more exposed metal pads of the first and second surface mount packages comprise a second output pad, wherein the second output pads of the first and second surface mount packages are each electrically connected to a respective one of the lower surface terminals of the first and second surface mount packages, wherein the second leads of the first and second discrete inductors are respectively electrically connected to the second output pads of the first and second surface mount packages.

Example 8. The semiconductor assembly of example 7, wherein the first and second leads of the first and second discrete inductors bend inward such that ends of the first and second leads are respectively disposed over the upper sides of the first and second surface mount packages.

Example 9. The semiconductor assembly of example 2, wherein the first and second discrete inductors are respectively thermally coupled to the upper sides of the first and second surface mount packages by an electrically isolating material arranged between the upper sides of the first and second surface mount packages and exposed parts of the metal element that respectively connect with the first and second leads of the first and second surface mount packages.

Example 10. The semiconductor assembly of example 1, wherein the first and second surface mount packages each comprise a power semiconductor die embedded within a laminate package body.

Example 11. The semiconductor assembly of example 1, wherein the first and second surface mount packages each comprise a power semiconductor die embedded within an electrically insulating mold compound.

Example 12. A method of forming a semiconductor assembly, the method comprising: providing a carrier comprising a dielectric substrate and a plurality of contact pads disposed on an upper surface of the carrier; mounting first and second surface mount packages on the carrier; and mounting first and second discrete inductors respectively over the first and second surface mount packages, wherein the first and second surface mount packages each comprise lower surface terminals that face and electrically connect with the contact pads from the carrier, wherein the first and second surface mount packages each comprise an upper side that faces away from the carrier, and wherein first and second discrete inductors are respectively thermally coupled to the upper sides of the first and second surface mount packages.

Example 13. The method of example 12, wherein mounting the first and second discrete inductors comprises applying a thermally conductive material to the upper side of the first and second surface mount packages and respectively arranging the first and second discrete inductors over the first and second surface mount packages such that the thermally conductive material is interposed between the upper sides of the first and second surface mount packages and lower sides of the first and second discrete inductors.

Example 14. The method of example 12, wherein the first and second surface mount packages each comprise a power semiconductor die embedded within a laminate package body.

Example 15. The method of example 12, wherein the first and second surface mount packages each comprise a power semiconductor die embedded within an electrically insulating mold compound.

Example 16. A semiconductor assembly, comprising: an interposer comprising a plurality of upper surface contact pads disposed on an upper surface of the interposer; first and second surface mount packages mounted on the interposer, the first and second surface mount packages each comprising lower surface terminals that face and electrically connect with the upper surface contact pads from the interposer; and first and second discrete inductors mounted over the first and second surface mount packages, respectively, wherein the first and second surface mount packages are each configured as a half-bridge circuit, wherein the first and second surface mount packages each comprise a switch output terminal that is respectively configured as a switch node of the half-bridge circuit from the first and second surface mount packages, and wherein the switch output terminals of the first and second surface mount packages are respectively electrically connected to first leads from the first and second discrete inductors.

Example 17. The semiconductor assembly of example 16, wherein the switch output terminals of the first and second surface mount packages are respectively electrically connected to the first leads from the first and second discrete inductors via the interposer.

Example 18. The semiconductor assembly of example 17, wherein the interposer comprises pairs of the upper surface contact pads that are immediately adjacent one another, and wherein the switch output terminals of the first and second surface mount packages are respectively electrically connected to the first leads from the first and second discrete inductors by the pairs of the upper surface contact pads that are immediately adjacent to one another.

Example 19. The semiconductor assembly of example 16, wherein the upper sides of the first and second surface mount packages each comprise an exposed metal pads that are respectively configured as the switch output terminals of the first and second surface mount packages, and wherein the switch output terminals of the first and second surface mount packages are respectively soldered to first leads from the first and second discrete inductors.

Example 20. The semiconductor assembly of example 16, wherein the lower surface terminals of the first and second surface mount packages each comprise a ground terminal pad and a voltage input pad, and wherein the interposer comprises a common ground connection that connects the ground terminal pads of the first and second surface mount packages together, and wherein the interposer comprises a common voltage supply connection that connects the voltage input pads of the first and second surface mount packages together.

Example 21. The semiconductor assembly of example 16, further comprising a circuit board comprising upper surface contact pads, wherein the interposer comprises a plurality of lower surface contact pads disposed on a lower surface of the interposer, wherein the lower surface contact pads of the interposer face and electrically connect with the upper surface contact pads of the circuit board.

Example 22. The semiconductor assembly of example 21, wherein the lower surface terminals of the first and second surface mount packages each comprise ground terminal pads and voltage input pads, and wherein the circuit board comprises common ground connections and common voltage input connections that are electrically connected to the ground terminal pads and the voltage input pads of the first and second surface mount packages.

The semiconductor dies disclosed herein can be formed in a wide variety of device technologies that utilize a wide variety of semiconductor materials. Examples of such materials include, but are not limited to, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGalnN) or indium gallium arsenide phosphide (InGaAsP), etc.

The semiconductor dies disclosed herein may be configured as a vertical device, which refers to a device that conducts a load current between opposite facing main and rear surfaces of the die. Alternatively, the semiconductor dies disclosed herein may be configured as a lateral device, which refers to a device that conducts a load current parallel to a main surface of the die.

The term “electrical connection” as used herein describes a low resistance electrical conduction path provided by one or more electrically conductive structures. An “electrical connection” may comprise multiple different electrically conductive structures such as bond pads, solder structures and interconnect lines.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

1. A semiconductor assembly, comprising:
a carrier comprising a dielectric substrate and a plurality of contact pads disposed on an upper surface of the carrier;
first and second surface mount packages mounted on the carrier;
first and second discrete inductors respectively mounted over the first and second surface mount packages,
wherein the first and second surface mount packages each comprise lower surface terminals that face and electrically connect with the contact pads from the carrier,
wherein the first and second surface mount packages each comprise an upper side that faces away from the carrier, and
wherein the first and second discrete inductors are respectively thermally coupled to the upper sides of the first and second surface mount packages.

2. The semiconductor assembly of claim 1, wherein the first and second discrete inductors each comprise an outer body of electrically insulating material, a metal element arranged within the outer body, and first and second leads that are exposed from the outer body, wherein the outer body of each of the first and second discrete inductors comprises a lower side that faces the carrier and an upper side that faces away from the carrier, and wherein the metal element of each of the first and second discrete inductors comprises a heat radiating block that is exposed at the upper side of the outer body of the respective first and second discrete inductors.

3. The semiconductor assembly of claim 2, wherein the upper sides of the first and second surface mount packages each comprise one or more exposed metal pads, and wherein the one or more exposed metal pads of the first and second surface mount packages are respectively thermally coupled to the metal element of the first and second discrete inductors.

4. The semiconductor assembly of claim 3, wherein the one or more exposed metal pads of the first and second surface mount packages comprise a first output pad, and wherein the first leads of the first and second discrete inductors are respectively electrically connected to the first output pads of the first and second surface mount packages.

5. The semiconductor assembly of claim 4, wherein the second leads of the first and second discrete inductors are respectively electrically connected to one of the contact pads disposed on the upper surface of the carrier.

6. The semiconductor assembly of claim 4, wherein the one or more exposed metal pads of the first and second surface mount packages comprise a dummy pad, wherein the first leads of the first and second discrete inductors are respectively soldered to the first output pads of the first and second surface mount packages, and wherein the second leads of the first and second discrete inductors are respectively soldered to the dummy pads of the first and second surface mount packages.

7. The semiconductor assembly of claim 4, wherein the one or more exposed metal pads of the first and second surface mount packages comprise a second output pad, wherein the second output pads of the first and second surface mount packages are each electrically connected to a respective one of the lower surface terminals of the first and second surface mount packages, wherein the second leads of the first and second discrete inductors are respectively electrically connected to the second output pads of the first and second surface mount packages.

8. The semiconductor assembly of claim 7, wherein the first and second leads of the first and second discrete inductors bend inward such that ends of the first and second leads are respectively disposed over the upper sides of the first and second surface mount packages.

9. The semiconductor assembly of claim 2, wherein the first and second discrete inductors are respectively thermally coupled to the upper sides of the first and second surface mount packages by an electrically isolating material arranged between the upper sides of the first and second surface mount packages and exposed parts of the metal element that respectively connect with the first and second leads of the first and second surface mount packages.

10. The semiconductor assembly of claim 1, wherein the first and second surface mount packages each comprise a power semiconductor die embedded within a laminate package body.

11. The semiconductor assembly of claim 1, wherein the first and second surface mount packages each comprise a power semiconductor die embedded within an electrically insulating mold compound.

12. A method of forming a semiconductor assembly, the method comprising:
providing a carrier comprising a dielectric substrate and a plurality of contact pads disposed on an upper surface of the carrier;
mounting first and second surface mount packages on the carrier; and
mounting first and second discrete inductors respectively over the first and second surface mount packages,
wherein the first and second surface mount packages each comprise lower surface terminals that face and electrically connect with the contact pads from the carrier,
wherein the first and second surface mount packages each comprise an upper side that faces away from the carrier, and
wherein first and second discrete inductors are respectively thermally coupled to the upper sides of the first and second surface mount packages.

13. The method of claim 12, wherein mounting the first and second discrete inductors comprises applying a thermally conductive material to the upper side of the first and second surface mount packages and respectively arranging the first and second discrete inductors over the first and second surface mount packages such that the thermally conductive material is interposed between the upper sides of the first and second surface mount packages and lower sides of the first and second discrete inductors.

14. The method of claim 12, wherein the first and second surface mount packages each comprise a power semiconductor die embedded within a laminate package body.

15. The method of claim 12, wherein the first and second surface mount packages each comprise a power semiconductor die embedded within an electrically insulating mold compound.

16. A semiconductor assembly, comprising:
an interposer comprising a plurality of upper surface contact pads disposed on an upper surface of the interposer;
first and second surface mount packages mounted on the interposer, the first and second surface mount packages each comprising lower surface terminals that face and electrically connect with the upper surface contact pads from the interposer; and
first and second discrete inductors mounted over the first and second surface mount packages, respectively,
wherein the first and second surface mount packages are each configured as a half-bridge circuit,
wherein the first and second surface mount packages each comprise a switch output terminal that is respectively configured as a switch node of the half-bridge circuit from the first and second surface mount packages, and
wherein the switch output terminals of the first and second surface mount packages are respectively electrically connected to first leads from the first and second discrete inductors.

17. The semiconductor assembly of claim 16, wherein the switch output terminals of the first and second surface mount packages are respectively electrically connected to the first leads from the first and second discrete inductors via the interposer.

18. The semiconductor assembly of claim 17, wherein the interposer comprises pairs of the upper surface contact pads that are immediately adjacent one another, and wherein the switch output terminals of the first and second surface mount packages are respectively electrically connected to the first leads from the first and second discrete inductors by the pairs of the upper surface contact pads that are immediately adjacent to one another.

19. The semiconductor assembly of claim 16, wherein the upper sides of the first and second surface mount packages each comprise an exposed metal pads that are respectively configured as the switch output terminals of the first and second surface mount packages, and wherein the switch output terminals of the first and second surface mount packages are respectively soldered to first leads from the first and second discrete inductors.

20. The semiconductor assembly of claim 16, wherein the lower surface terminals of the first and second surface mount packages each comprise a ground terminal pad and a voltage input pad, and wherein the interposer comprises a common ground connection that connects the ground terminal pads of the first and second surface mount packages together, and wherein the interposer comprises a common voltage supply connection that connects the voltage input pads of the first and second surface mount packages together.

21. The semiconductor assembly of claim 16, further comprising a circuit board comprising upper surface contact pads, wherein the interposer comprises a plurality of lower surface contact pads disposed on a lower surface of the interposer, wherein the lower surface contact pads of the interposer face and electrically connect with the upper surface contact pads of the circuit board.

22. The semiconductor assembly of claim 21, wherein the lower surface terminals of the first and second surface mount packages each comprise ground terminal pads and voltage input pads, and wherein the circuit board comprises common ground connections and common voltage input connections that are electrically connected to the ground terminal pads and the voltage input pads of the first and second surface mount packages.
